(19) United States
(12) Patent Application Publication
(10) Pub. No.: US 2009/0189295 A1
(43) Pub. Date: Jul. 30, 2009

(54) STACK CHIP PACKAGE STRUCTURE AND MANUFACTURING METHOD THEREOF

(75) Inventors: Yueh-Ming TUNG, Fengshan City (TW); Chia-Ming Yang, Tainan City (TW); Shu-Hui Lin, Gangshan Township (TW); Ta-Fa Lin, Kaohsiung City (TW); Mien-Fang Sung, Kaohsiung City (TW)

Correspondence Address: Muncy, Geissler, Olds & Lowe, PLLC, P.O. BOX 1364, FAIRFAX, VA, 22038-1364, US

(73) Assignee: ORIENT SEMICONDUCTOR ELECTRONICS, LTD.

(21) Appl. No.: 12/120,095

(22) Filed: May 13, 2008

(30) Foreign Application Priority Data
Jan. 28, 2008 (TW) 97103171

(51) Int. Cl. H01L 21/50; H01L 23/48

(52) U.S. Cl. 257/778; 438/107; 257/E23.01; 257/E21.499

(57) ABSTRACT

A stack chip package structure and a manufacturing method thereof are disclosed. The method comprises: providing a first substrate; disposing a first chip on the first substrate; disposing a second chip and at least one second substrate on the first chip, wherein the second substrate is electrically connected to the first chip; bonding at least one first connecting wire connected between the second chip and the second substrate; bonding at least one second connecting wire connected between the first substrate and the second substrate; and forming a package body on the first substrate to encapsulate the first chip, the second chip, the second substrate, the first connecting wire and the second connecting wire.

### RELATED APPLICATIONS

This application claims priority to Taiwan Application Serial Number 97103171, filed Jan. 28, 2008, which is herein incorporated by reference.

### FIELD OF THE INVENTION

This invention relates to a stack chip package structure and a manufacturing method thereof, and more particularly, to a stack chip package structure and a manufacturing method thereof to prevent too many wires from bonding to a single substrate.

### BACKGROUND OF THE INVENTION

In the semiconductor manufacturing process, IC packaging is an important step therein to protect the IC chip and provide the external electrical connection, thereby preventing the chip from damage when being moved or transported. Further, the IC element may have passive elements, such as resistance or capacitance, to form a functioning IC system, and the electronic package can provide the IC element with protection and structure maintenance. In general, the electronic package after the IC chip is manufactured includes chip bonding, circuit connection, encapsulating, bonding with circuit board, system combination and other steps. Therefore, the electronic package can combine the IC chip and other electronic elements, transmit electrical signals, dissipate the heat, hold and protect the structure.

In modern electronic devices, plenty of electronic elements or chips are disposed in a single device to carry out multiple functions, thereby satisfying the user's needs. However, the chips are formed in different packaging structures respectively in the electronic device, and thus enlarge the space thereof. Therefore, a stack chip package structure is used to increase the packaging density and reduce the total space of the packaging structures. In the conventional stack chip package structure, a plurality of chips are stacked on a substrate, and all the inputs/outputs (I/O) of the chips are electrically connected to a plurality of bonding pads disposed on the substrate by wire bonding.

However, since all the bonding pads for electrically connecting to the inputs/outputs are disposed on the single substrate, the amount of the bonding pads and the area of the substrate need to be increased, and the space of the package structure is enlarged. Alternatively, the pitch between the bonding pads on the substrate has to be reduced, and thus it is difficult for the wire bonding process.

### SUMMARY OF THE INVENTION

Therefore, an aspect of the present invention is to provide a stack chip package structure and a manufacturing method thereof to allow a chip of the stack chip to be electrically connected to a second substrate, thereby reducing the area of the first substrate and the space of the stack chip package structure.

Another aspect of the present invention is to provide a stack chip package structure and a manufacturing method thereof to prevent too many wires from bonding to a single substrate, thereby enhancing the yield of the manufacturing process.

According to an embodiment of the present invention, the stack chip package structure comprises a first substrate, a first chip, a second chip, at least one second substrate, at least one first connecting wire, at least one second connecting wire and a package body. The first chip is disposed on the first substrate. The second chip is disposed on the first chip. The second substrate is disposed on the first chip and electrically connected to the first substrate and the first chip. The first connecting wire is connected between the second chip and the second substrate. The second connecting wire is connected between the first substrate and the second substrate. The package body is formed on the first substrate to encapsulate the first chip, the second chip, the second substrate, the first connecting wire and the second connecting wire.

According to another embodiment of the present invention, the method for manufacturing a stack chip package structure comprises: providing a first substrate; disposing a first chip on the first substrate; disposing a second chip and at least one second substrate on the first chip, wherein the second substrate is electrically connected to the first chip; bonding at least one first connecting wire connected between the second chip and the second substrate; bonding at least one second connecting wire connected between the first substrate and the second substrate; and forming a package body on the first substrate to encapsulate the first chip, the second chip, the second substrate, the first connecting wire and the second connecting wire.

Therefore, with the application of the stack chip package structure and the manufacturing method thereof disclosed in the embodiments of the present invention, the chips stacked can be electrically connected to a second substrate, thereby preventing too many wires from bonding to a single substrate to reduce the space of the stack chip package structure and enhance the yield of the manufacturing process.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 A is a cross-sectional view showing a stack chip package structure according to a first embodiment of the present invention;

FIG. 1 B is a top view showing a stack chip package structure according to a first embodiment of the present invention;

FIG. 2 A is a cross-sectional view showing a stack chip package structure according to a second embodiment of the present invention;

FIG. 2 B is a top view showing a stack chip package structure according to a second embodiment of the present invention;

FIG. 3 A is a cross-sectional view showing a stack chip package structure according to a third embodiment of the present invention; and

FIG. 3 B is a top view showing a stack chip package structure according to a third embodiment of the present invention.

### DETAILED DESCRIPTION OF THE PREFERRED EMBODIMENT

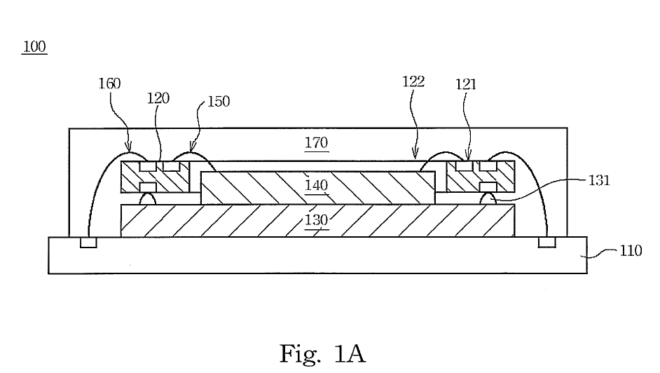

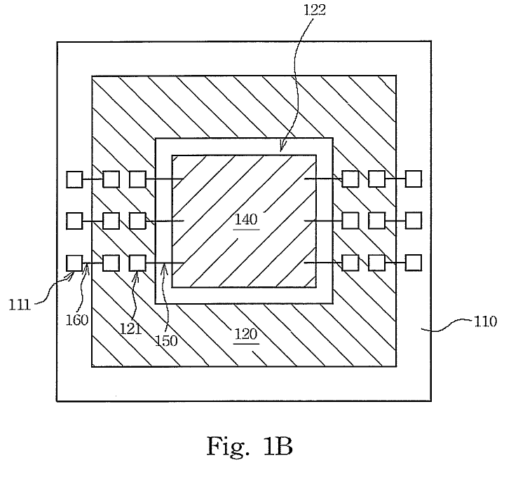

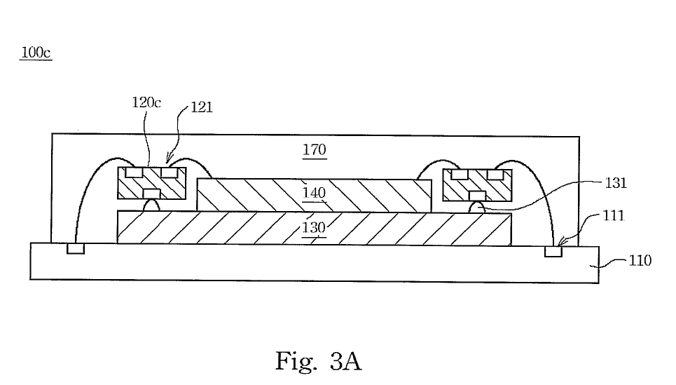

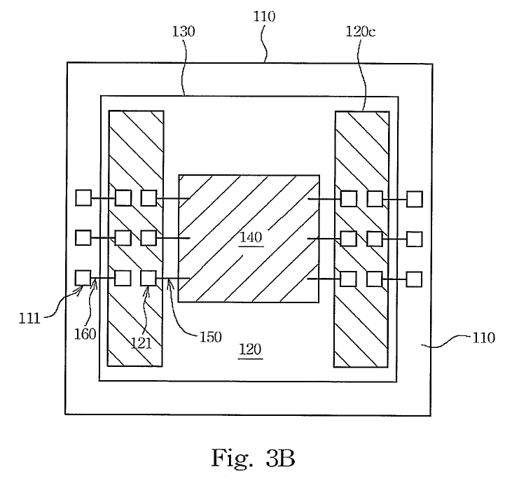

In order to make the illustration of the present invention more explicit and complete, the following description is stated with reference to FIG. 1 A through FIG. 3B.

Refer to FIG. 1 A and FIG. 1 B. FIG. 1 A is a cross-sectional view showing a stack chip package structure according to a first embodiment of the present invention, and FIG. 1 B is a top view showing a stack chip package structure according to a first embodiment of the present invention. The stack chip package structure 100 comprises a first substrate 110, at least one second substrate 120, a first chip 130, a second chip 140, at least one first connecting wire 150, at least one second connecting wire 160 and a package body 170. The first chip 130 is disposed on the first substrate 110. The second chip 140 is disposed on the first chip 130. The second substrate 120 is disposed on the first chip 130 and electrically connected to the first substrate 110 and the first chip 130. The first connecting wire 150 is electrically connected between the second chip 140 and the second substrate 120. The second connecting wire 160 is electrically connected between the first substrate 110 and the second substrate 120. The package body 170 is formed on the first substrate 110 and encapsulates the first chip 130, the second chip 140, the second substrate 120, the first connecting wire 150 and the second connecting wire 160. The first substrate 110 may include at least one input/output (I/O) at the front side or the rear side thereof to electrically connect other electronic devices (not shown). For example, the first substrate 110 of the stack chip package structure 100 may be a substrate or a lead-frame, and the first substrate 110 includes a plurality of solder balls or leads to be the inputs/outputs at the rear side thereof to be electrically connected to a carrier, such as a printed circuit board (PCB), a flexible printed circuit (FPC) or a motherboard. Alternatively, the stack chip package structure 100 may include a plurality of gold fingers to be the inputs/outputs at the front side or the rear side thereof to insert in a socket of an electronic device for electrical connection.

Refer to FIG. 1 A and FIG. 1 B again. The first substrate 110 of the present embodiment may be made of a dielectric material, such as Bismaleimide Triazine (BT), epoxy resin, ceramics or organic glass fiber. The first substrate 110 includes at least one bonding pad 111, wherein the second connecting wire 160 is connected to the bonding pad 111. In an embodiment, the first substrate 110 may further include at least one passive component, such as a capacitance, an inductance or a resistance. The passive component may be disposed on the first substrate 110, or embedded in the first substrate 110.

Refer to FIG. 1 A and FIG. 1 B again. The first chip 130 of the present embodiment is mounted on the first substrate 110. In the present embodiment, the first chip 130 may be mounted on the first substrate 110 by a method of surface mount technology (SMT). Before the first chip 130 is mounted on the first substrate 110, at least one metal bump 131 (such as solder ball) is formed on the front face (i.e. an active surface) of the first chip 130, so that the second substrate 120 can be electrically connected to the first chip 130 by the metal bump 131. The metal bump 131 may be made of tin, aluminum, nickel, silver, copper, indium or alloys thereof.

Refer to FIG. 1 A and FIG. 1 B again. The second substrate 120 of the present embodiment may be made of dielectric material, such as Bismaleimide Triazine (BT), epoxy resin, ceramics or organic glass fiber. The second substrate 120 includes a plurality of bonding pads 121 formed on two opposite sides thereof to be electrically connected to the first chip 130, the second chip 140 and the second connecting wire 160. In the present embodiment, the second substrate 120 has an opening 122, and a portion of the surface of the first chip 130 is exposed through the opening 122, wherein the area of the opening 122 is larger than the area of the second chip 140. At this time, the second chip 140 is disposed in the opening 122 of the second substrate 120 and mounted on the exposed surface of the first chip 130 by such as a method of SMT.

Refer to FIG. 1 A and FIG. 1 B again. The first connecting wire 150 and the second connecting wire 160 of the present embodiment may be gold wires, silver wires, copper wires or aluminum wires. The first connecting wire 150 is connected between the second chip 140 and the bonding pads 121 of the second substrate 120 to electrically connect the second chip 140 and the second substrate 120. The second connecting wire 160 is connected between the first substrate 110 and the bonding pads 121 of the second substrate 120 to electrically connect the first substrate 110 and the second substrate 120. The package body 170 may be made of epoxy resin, PMMA, polycarbonate or silica material. The package body 170 is formed on the first substrate 110 to encapsulate the first chip 130, the second chip 140, the second substrate 120, the first connecting wire 150 and the second connecting wire 160, thereby forming the stack chip package structure 100.

When manufacturing the stack chip package structure 100 of the present embodiment, first, the first chip 130 is disposed on the first substrate 110. Next, the second substrate 120 and the second chip 140 are disposed on the first chip 130. Next, a wire bonding step bonds the first connecting wire 150 connected between the second chip 140 and the second substrate 120 and the second connecting wire 160 connected between the first substrate 110 and the second substrate 120. Then, the package body 170 is formed on the first substrate 110, thereby forming the stack chip package structure 100.

It is worth mentioning that the manufacturing sequence of the stack chip package structure 100 is not limited to the above description. When disposing the second substrate 120 and the second chip 140, first, the second substrate 120 may be bonded to the metal bump 131 of the first chip 130, and then the second chip 140 is mounted on the exposed surface of the first chip 130. Alternatively, the second chip 140 is mounted on the exposed surface of the first chip 130 first, and then the second substrate 120 is bonded to the metal bump 131 thereof.

The first chip 130 and the second chip 140 are electrically connected to the second substrate 120 by the metal bump and wire bonding, and the second substrate 120 is electrically connected to the first substrate 110. Therefore, the first chip 130 and the second chip 140 can be electrically connected to the first substrate 110 through the inter connecting of the second substrate 120, thereby reducing the number of bonding pads 111 on the first substrate 110 and preventing too many wires from bonding to a single substrate. By using of the second substrate 120, the problems of the substrate area and the pitch between the bonding pads can be resolved, and thus the space of the stack chip package structure can be reduced, and the yield of the manufacturing process can be enhanced.

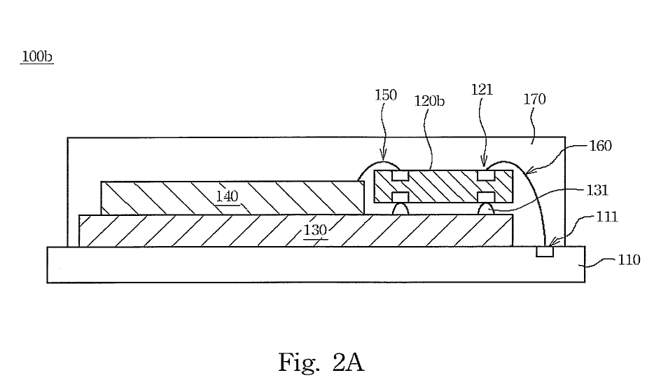

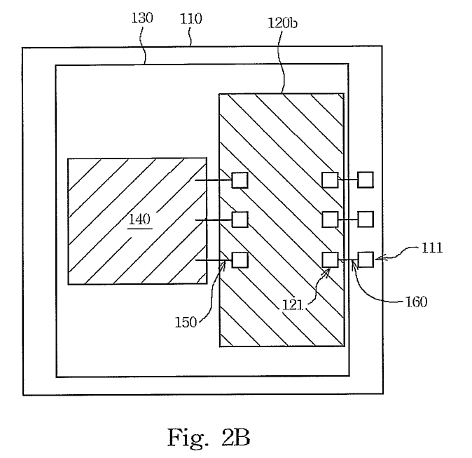

Refer to FIG. 2 A and FIG. 2 B. FIG. 2 A is a cross-sectional view showing a stack chip package structure according to a second embodiment of the present invention, and FIG. 2 B is a top view showing a stack chip package structure according to a second embodiment of the present invention. Same reference numerals shown in the first embodiment are used in the second embodiment of the present invention. The construction shown in the second embodiment is similar to that in the first embodiment with respect to configuration and function, and thus is not stated in detail herein.

Refer again to FIG. 2 A and FIG. 2 B. In comparison with the first embodiment, the second substrate 120b of the stack chip package structure 100b of the second embodiment may not include the opening 122. At this time, the second substrate 120b and the second chip 140 are mounted on the first substrate 110, and the second substrate 120b may be disposed at one side of the second chip 140 and electrically connected to the metal bump 131 of the first chip 130. The first connecting wire 150 is electrically connected between the second chip 140 and the second substrate 120b. The second connecting wire 160 is electrically connected between the first substrate 110 and the second substrate 120b. Therefore, the first chip 130 and the second chip 140 can be electrically connected to the first substrate 110 through the second substrate 120b, thereby reducing the space of the stack chip package structure and enhancing the yield of the manufacturing process.

Refer to FIG. 3 A and FIG. 3 B. FIG. 3 A is a cross-sectional view showing a stack chip package structure according to a third embodiment of the present invention, and FIG. 3 B is a top view showing a stack chip package structure according to a third embodiment of the present invention. Same reference numerals shown in the second embodiment are used in the third embodiment of the present invention. The construction shown in the third embodiment is similar to that in the second embodiment with respect to configuration and function, and thus is not stated in detail herein.

Refer again to FIG. 3 A and FIG. 3 B. In comparison with the second embodiment, the stack chip package structure 100c of the third embodiment comprises two second substrates 120c. At this time, the second substrates 120c and the second chip 140 are mounted on the first substrate 110, and the second substrates 120c may be disposed at two sides of the second chip 140 and electrically connected to the metal bump 131 of the first chip 130. The first connecting wire 150 is electrically connected between the second chip 140 and the second substrates 120c. The second connecting wire 160 is electrically connected between the first substrate 110 and the second substrates 120c. Therefore, the first chip 130 and the second chip 140 can be electrically connected to the first substrate 110 through the second substrates 120c, thereby reducing the space of the stack chip package structure and enhancing the yield of the manufacturing process.

Therefore, the stack chip package structure shown in the respective embodiments of the present invention can prevent too many wires from bonding to a single substrate, thereby reducing the space of the stack chip package structure and enhancing the yield of the manufacturing process.

As is understood by a person skilled in the art, the foregoing embodiments of the present invention are strengths of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A stack chip package structure, comprising:
a first substrate;
a first chip disposed on the first substrate;
a second chip disposed on the first chip;
at least one second substrate disposed on the first chip and electrically connected to the first substrate and the first chip;
at least one first connecting wire connected between the second chip and the second substrate;
at least one second connecting wire connected between the first substrate and the second substrate; and
a package body formed on the first substrate to encapsulate the first chip, the second chip, the second substrate, the first connecting wire and the second connecting wire.

2. The stack chip package structure as claimed in claim 1, wherein the first substrate includes at least one bonding pad and the second connecting wire is connected to the bonding pad.

3. The stack chip package structure as claimed in claim 1, wherein the second substrate has an opening, and the second chip is disposed in the opening and mounted on the first chip.

4. The stack chip package structure as claimed in claim 1, wherein the second substrate is disposed at one side of the second chip.

5. The stack chip package structure as claimed in claim 1, wherein the stack chip package structure comprises two second substrates disposed on two sides of the second chip.

6. The stack chip package structure as claimed in claim 1, wherein the first substrate includes at least one passive component.

7. The stack chip package structure as claimed in claim 1, wherein the first connecting wire and the second connecting wire are gold wires, silver wires, copper wires or aluminum wires.

8. The stack chip package structure as claimed in claim 1, wherein the package body is made of epoxy resin, PMMA, polycarbonate or silica material.

9. The stack chip package structure as claimed in claim 1, wherein the first chip includes at least one metal bump to be electrically connected to the second substrate.

10. The stack chip package structure as claimed in claim 1, wherein the metal bump is made of tin, aluminum, nickel, silver, copper, indium or alloys thereof.

11. A method for manufacturing a stack chip package structure, comprising:
providing a first substrate;
disposing a first chip on the first substrate;
disposing a second chip and at least one second substrate on the first chip, wherein the second substrate is electrically connected to the first chip;
bonding at least one first connecting wire connected between the second chip and the second substrate;
bonding at least one second connecting wire connected between the first substrate and the second substrate; and
forming a package body on the first substrate to encapsulate the first chip, the second chip, the second substrate, the first connecting wire and the second connecting wire.

12. The method as claimed in claim 11, wherein the first chip is disposed on the first substrate using surface mount technology (SMT).

13. The method as claimed in claim 11, wherein the second chip is disposed on the first chip using surface mount technology (SMT).

14. The method as claimed in claim 11, wherein the second substrate has an opening, and the second chip is disposed in the opening and mounted on the first chip.

15. The method as claimed in claim 11, wherein the second substrate is disposed at one side of the second chip.

16. The method as claimed in claim 11, wherein the disposing the second substrate step comprises:
disposing two second substrates at two sides of the second chip.

17. The method as claimed in claim 11, wherein the first connecting wire and the second connecting wire are gold wires, silver wires, copper wires or aluminum wires.

18. The method as claimed in claim 11, wherein the package body is made of epoxy resin, PMMA, polycarbonate or silica material.

19. The method as claimed in claim 11, further comprising:
forming at least one metal bump on the first chip to be electrically connected to the second substrate.

20. The method as claimed in claim 19, wherein the metal bump is made of tin, aluminum, nickel, silver, copper, indium or alloys thereof.
